(19) United States
(12) Patent Application Publication
(10) Pub. No.: US 2012/0243384 A1
(43) Pub. Date: Sep. 27, 2012

(54) PIEZOELECTRIC VIBRATOR, OSCILLATOR, ELECTRONIC APPARATUS AND RADIO-CONTROLLED TIMEPIECE

(76) Inventor: Yoichi Funabiki, Chiba-shi (JP)

(21) Appl. No.: 13/419,619

(22) Filed: Mar. 14, 2012

(30) Foreign Application Priority Data
Mar. 22, 2011 (JP) 2011-062003

(51) Int. Cl. H01L 41/22; H03B 5/32; G04C 11/02; H01L 41/053

(52) U.S. Cl. 368/47; 29/25.35; 310/344; 331/158

(57) ABSTRACT

Provided is a piezoelectric vibrator which is also compatible with the miniaturization thereof. In a piezoelectric vibrator where a piezoelectric vibrating piece is sealed in a cavity formed between a lid substrate and a base substrate made of a glass material, one through hole is formed in the base substrate, a pair of through electrodes are arranged in the through hole, the through hole is filled with a glass frit and the glass frit is solidified by baking so that the through hole is sealed by the glass fit. By arranging the pair of through electrodes in one through hole, one through hole is provided for one piezoelectric vibrator and hence, bending strength of the base substrate can be increased. Further, the piezoelectric vibrator is compatible with the miniaturization thereof.

### RELATED APPLICATIONS

This application claims priority under 35 U.S.C. §119 to Japanese Patent Application No. 2011-062003 filed on Mar. 22, 2011, the entire content of which is hereby incorporated by reference.

### BACKGROUND OF THE INVENTION

1. Field of the Invention

The present invention relates to a piezoelectric vibrator, an oscillator, an electronic apparatus and a radio-controlled timepiece.

2. Description of the Related Art

Recently, in a mobile phone and a personal digital assistant, as a time source, a timing source for a control signal or the like, a reference signal source or the like, a piezoelectric vibrator which uses crystal or the like is used.

The piezoelectric vibrator includes a base substrate and a lid substrate which are bonded to each other, and a piezoelectric vibrating piece which is sealed in a cavity (hollow portion) C which is formed between both substrates.

The piezoelectric vibrating piece is, for example, a tuning-fork-type vibrating piece, and is mounted on an upper surface of the base substrate in the cavity C.

The base substrate and the lid substrate are formed of a glass substrate.

On the base substrate, a pair of through holes which penetrates the base substrate in the thickness direction is formed corresponding to a pair of electrodes formed on the vibrating piece. A conductive member is embedded in the pair of through holes so as to close the through holes thus forming through electrodes.

The through electrodes are electrically connected with external electrodes which are formed on an outer surface (lower surface) of the base substrate, and are electrically connected with the piezoelectric vibrating piece which is mounted in the cavity C.

In a conventional piezoelectric vibrator, as disclosed in JPA-2002-124845, a pair of cylindrical through holes is formed in a glass package using a mold, and both through holes are filled with a silver paste thus forming a through electrode.

Further, there has been also proposed a method where, in a glass package, a pair of through holes having a trapezoidal shape in cross section is formed in a glass package, and a metal pin (through electrode) is arranged in each through hole, and low-melting-point glass is filled in the through holes.

### SUMMARY OF THE INVENTION

However, in an attempt to miniaturize the glass package, there arises a drawback that it is difficult to arrange a plurality of through holes. This is because when the pair of through holes is formed close to each other, there exists a possibility that a glass substrate will be chipped in an area between both through holes. Accordingly, with the conventional constitution where the pair of through holes is formed in the glass substrate, it is difficult to miniaturize a piezoelectric vibrator while satisfying durability of the piezoelectric vibrator.

The present invention has been made in view of such circumstances, and it is an object of the present invention to provide a piezoelectric vibrator which can be miniaturized while satisfying durability thereof.

To achieve the above-mentioned object by overcoming the above-mentioned drawbacks, according to one aspect of the present invention, there is provided a piezoelectric vibrator which includes: a base substrate which is made of a glass material; a lid substrate which is bonded to the base substrate; a recessed portion for cavity which is formed on at least either the lid substrate or the base substrate; one through hole which is formed in the base substrate; a pair of through electrodes which are arranged in the through hole; a sealing glass which holds the pair of through electrodes and seals the through hole; a piezoelectric vibrating piece having a pair of electrodes formed thereon, the pair of electrodes being electrically connected to the pair of through electrodes, and the piezoelectric vibrating piece being mounted on the base substrate in a state where the piezoelectric vibrating piece is housed in the cavity; and a pair of external electrodes which are mounted on a lower surface of the base substrate and are respectively electrically connected to the pair of through electrodes.

According to the present invention, one through hole is formed in the base substrate and a pair of through electrodes is arranged in the through hole. Accordingly, the piezoelectric vibrator can be miniaturized compared to a case where two through holes are formed in the base substrate.

### BRIEF DESCRIPTION OF THE DRAWINGS

FIG. 1 is a schematic constitutional view of a piezoelectric vibrator according to the present invention;

FIG. 2 is an internal constitutional view of the piezoelectric vibrator according to the present invention;

FIG. 3 is a cross-sectional view of the piezoelectric vibrator taken along a line A-A in FIG. 2;

FIG. 4 is a schematic constitutional view of the piezoelectric vibrator according to the present invention;

FIG. 5 is a top plan view of a piezoelectric vibrating piece according to the present invention;

FIG. 6 is a bottom plan view of the piezoelectric vibrating piece according to the present invention;

FIG. 7 is a cross-sectional view as viewed in the direction indicated by an arrow B-B in FIG. 5;

FIG. 8 is a flowchart for explaining the flow of manufacturing steps of the piezoelectric vibrator according to the present invention;

FIG. 9 is a view showing a manufacturing step of the piezoelectric vibrator according to the present invention;

FIG. 10A and FIG. 10B are views showing a manufacturing step of the piezoelectric vibrator according to the present invention;

FIGS. 11A to 11E are views showing a manufacturing step of the piezoelectric vibrator according to the present invention;

FIGS. 12A to 12D are views showing a manufacturing step of the piezoelectric vibrator according to the present invention;

FIG. 13 is a view showing a manufacturing step of the piezoelectric vibrator according to the present invention;

FIG. 14 is a view showing the whole base substrate forming wafer according to the present invention;

FIG. 15 is a view showing a manufacturing step of the piezoelectric vibrator according to the present invention;

FIG. 16 is a view showing a manufacturing step of the piezoelectric vibrator according to the present invention;

FIG. 17 is a schematic constitutional view of an oscillator according to the present invention;

FIG. 18 is a schematic constitutional view of an electronic apparatus according to the present invention; and

FIG. 19 is a schematic constitutional view of a radio-controlled timepiece according to the present invention.

### DETAILED DESCRIPTION OF THE PREFERRED EMBODIMENTS

### (1) Overview of the Embodiment

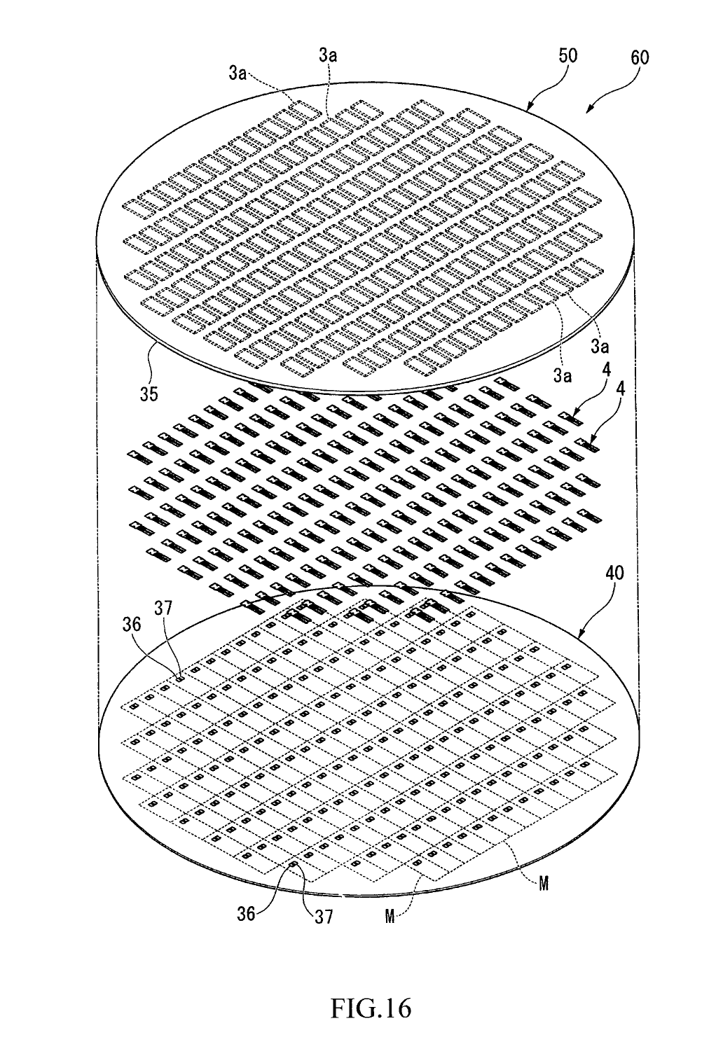

Firstly, a base substrate forming wafer 40 and a lid substrate forming wafer 50 shown in FIG. 16 are prepared. These wafers are made of soda lime glass.

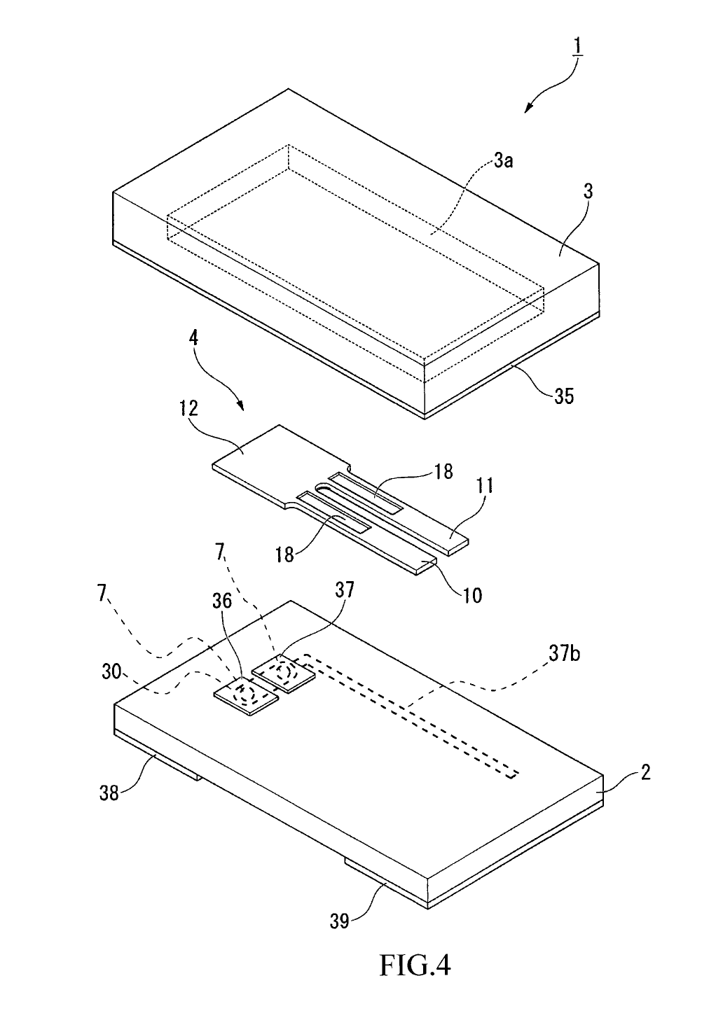

In the base substrate forming wafer 40, only one through hole 30 (see FIG. 4) which is larger than a through hole formed in a conventional base substrate forming wafer is formed. Two through electrodes 7 are arranged in the through hole 30. Sealing glass 6 is filled in the through hole 30, and the through electrodes 7 are fixed in the through hole 30 by the sealing glass 6 and the through hole 30 is sealed by the sealing glass 6.

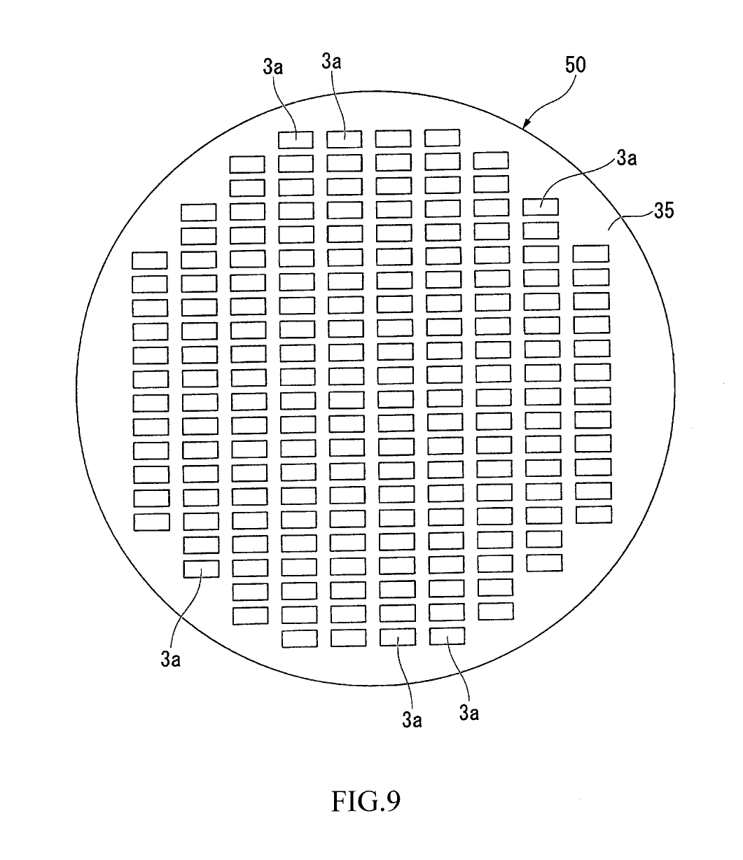

As shown in FIG. 9, a plurality of recessed portions 3a each of which forms a cavity C are formed on the lid substrate forming wafer 50, and a bonding film 35 is formed on a recessed-portion-3a side surface of the lid substrate forming wafer 50. On the other hand, on the base substrate forming wafer 40, piezoelectric vibrating pieces 4 are mounted. Then, a wafer body is formed by bonding the base substrate forming wafer 40 and the lid substrate forming wafer 50 to each other by anodic bonding. Thereafter, a plurality of piezoelectric vibrators can be manufactured by cutting the wafer body formed by bonding the wafers along cutting lines.

### (2) Detail of Embodiment

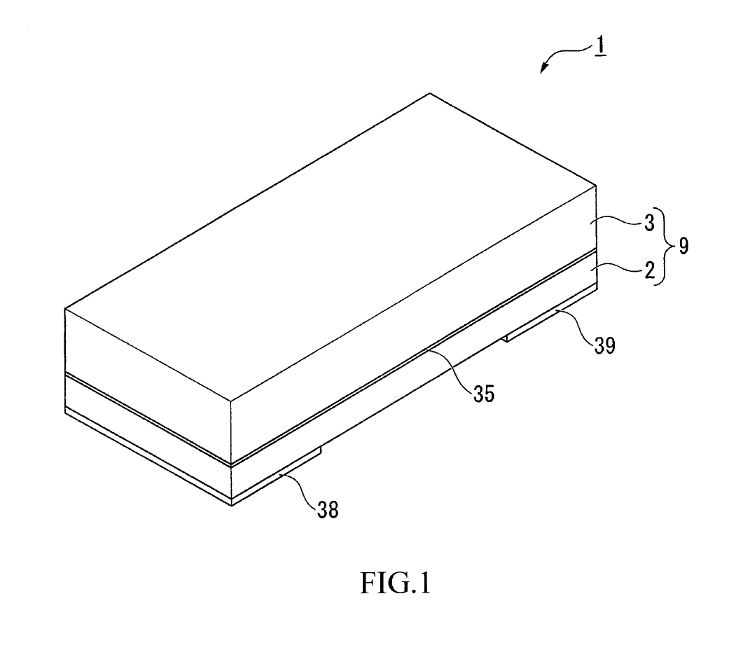

FIG. 1 to FIG. 4 show the constitution of the piezoelectric vibrator 1.

As shown in the drawings, the piezoelectric vibrator 1 of this embodiment is mainly constituted of a base substrate 2, a lid substrate 3 and a piezoelectric vibrating piece 4.

The piezoelectric vibrator 1 is a piezoelectric vibrator of a SMD (surface mount device) type which includes a package 9 having the base substrate 2 and the lid substrate 3 which overlap each other so as to form a cavity C, the piezoelectric vibrating piece 4 which is housed in the cavity C and is electrically connected to routing electrodes (internal electrodes) 36, 37 described later.

In this embodiment, the cavity C is formed by forming the recessed portion 3a on a lid substrate 3 side. However, the cavity C may be formed by forming a recessed portion on a base substrate 2 side or by forming a recessed portion on both the base substrate 2 and the lid substrate 3.

### (3) Piezoelectric Vibrating Piece

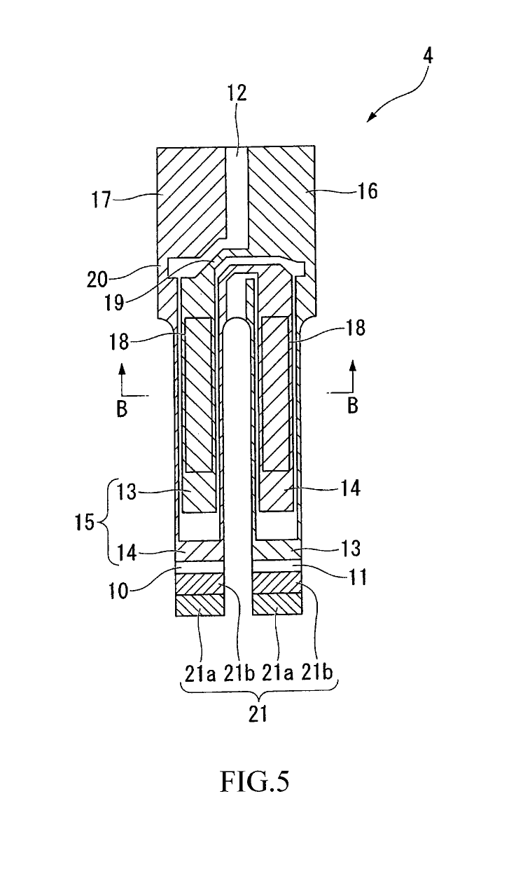

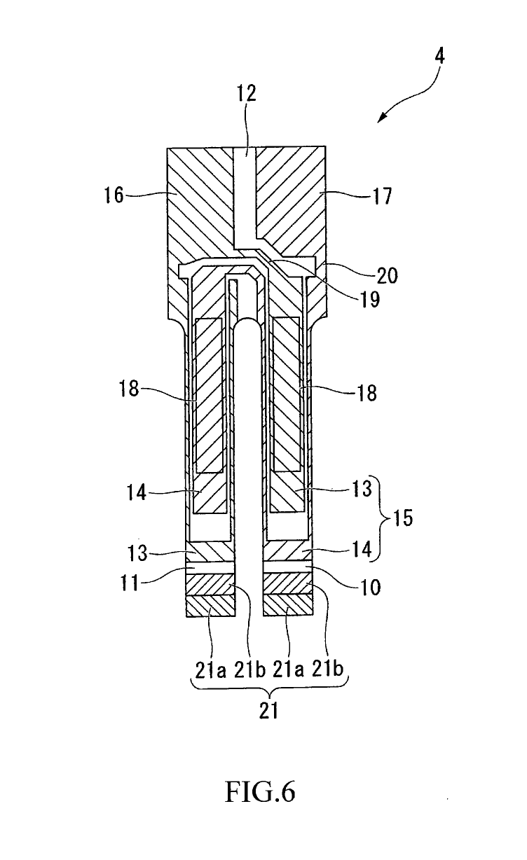

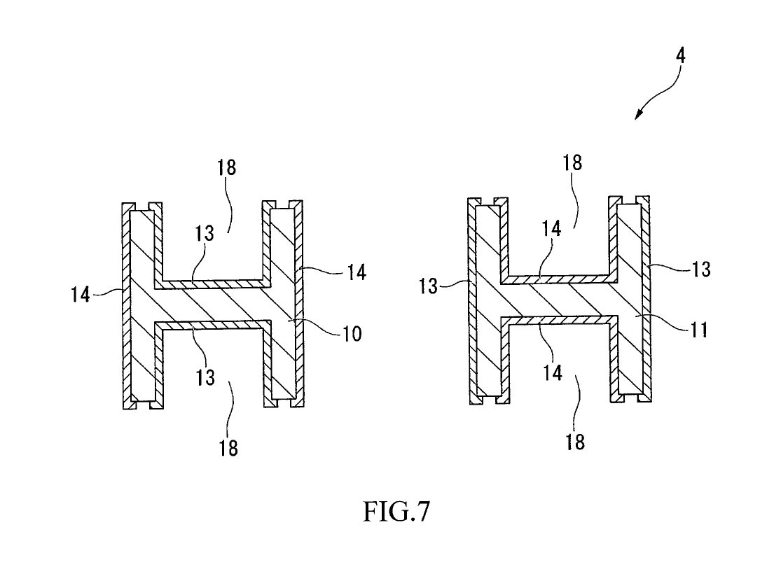

As shown in FIG. 5 to FIG. 7, the piezoelectric vibrating piece 4 is a tuning-fork-type vibrating piece which is made of a piezoelectric material such as crystal, lithium tantalate, or lithium niobate, and the piezoelectric vibrating piece 4 is vibrated when a predetermined voltage is applied thereto. The piezoelectric vibrating piece 4 includes a pair of vibrating arm portions 10, 11 which is arranged parallel to each other, a base portion 12 to which proximal end sides of the pair of vibrating arm portions 10, 11 are integrally fixed, an excitation electrode 15 which is constituted of a first excitation electrode 13 and a second excitation electrode 14 which are formed on outer surfaces of the proximal end portions of the pair of vibrating arm portions 10, 11 so as to vibrate the pair of vibrating arm portions 10, 11, and mount electrodes 16, 17 which are electrically connected to the first excitation electrode 13 and the second excitation electrode 14 respectively. Further, a groove portion 18 is formed on both main surfaces of the pair of vibrating arm portions 10, 11 respectively along the longitudinal direction of the vibrating arm portions 10, 11. The groove portion 18 extends from a proximal end side to an area in the vicinity of an intermediate portion of the vibrating arm portion 10, 11.

The excitation electrode 15 which is constituted of the first excitation electrode 13 and the second excitation electrode 14 is an electrode for vibrating the pair of vibrating arm portions 10, 11 in the direction that the vibrating arm portions 10, 11 approach each other or are separated from each other with predetermined resonance frequency. The excitation electrode 15 is formed on outer surfaces of the pair of vibrating arm portions 10, 11 by patterning. To be more specific, the first excitation electrode 13 is mainly formed on the groove portions 18 of one vibrating arm portion 10 and on both side surfaces of the other vibrating arm portion 11, while the second excitation electrode 14 is mainly formed on both side surfaces of one vibrating arm portion 10 and on the groove portions 18 of the other vibrating arm portion 11.

The first excitation electrode 13 and the second excitation electrode 14 are electrically connected to the mount electrodes 16, 17 respectively on both main surfaces of the base portions 12 via routing electrodes 19, 20. A voltage is applied to the piezoelectric vibrating piece 4 via the mount electrodes 16, 17.

The excitation electrode 15, the mount electrodes 16, 17 and the routing electrodes 19, 20 are formed of a conducive film made of chromium (Cr), nickel (Ni), aluminum (Al), titanium (Ti) or the like, for example.

A weight metal film 21 is formed on distal end portions of the pair of vibrating arm portions 10, 11 by coating respectively. The weight metal film 21 is provided to perform the frequency adjustment such that the vibrating arm portions 10, 11 per se are vibrated in a vibration state where the vibrations fall within a predetermined frequency range.

The weight metal film 21 is formed of a coarse adjustment film 21 a which is used for coarsely adjusting the frequency and a fine adjustment film 21b which is used for finely adjusting the frequency. The coarse adjustment film 21a is formed closer to a distal end portion side of the vibrating arm portions 10, 11 than the fine adjustment film 21b.

By performing the frequency adjustment using the coarse adjustment film 21a and the fine adjustment film 21b, it is possible to make the frequency of the pair of vibrating arm portions 10, 11 fall within a range of target frequency of the device.

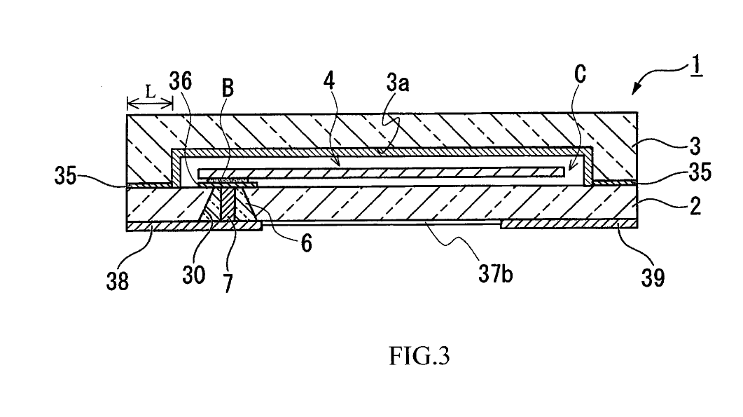

The piezoelectric vibrating piece 4 having such a constitution is, as shown in FIG. 3, bonded to an upper surface (cavity-C-side surface) of the base substrate 2. To be more specific, the routing electrodes 36, 37 which are formed on an inner surface of the base substrate 2 by patterning and the pair of mount electrodes 16, 17 of the piezoelectric vibrating piece 4 are bonded to each other using bumps B made of gold or the like respectively by bump bonding. Due to such a constitution, the piezoelectric vibrating piece 4 is supported in a spaced-apart manner from the upper surface of the base substrate 2, and also the mount electrodes 16, 17 and the routing electrodes 36, 37 are respectively electrically connected to each other via the bumps B.

In this embodiment, the vibrating arm portions 10, 11 of the piezoelectric vibrating piece 4 are spaced apart from the base substrate 2 due to the bumps B, a recessed portion may be also formed on an inner side of the base substrate 2 in an area corresponding to the vibrating arm portions 10, 11 and the vibrating arm portions 10, 11 may be spaced apart from the base substrate 2 by a stepped portion formed by the recessed portion. In this case, the recessed portion formed on the base substrate 2 also defines the cavity C.

### (4) Piezoelectric Vibrator

As shown in FIG. 1 to FIG. 4, the piezoelectric vibrator 1 of this embodiment includes the package 9 which is formed by laminating the base substrate 2 and the lid substrate 3 in two layers. The base substrate 2 is a transparent insulation substrate made of a glass material such as soda-lime glass, for example, and has a plate shape. In this embodiment, the base substrate 2 is formed so as to have a thickness of 400 μm, for example.

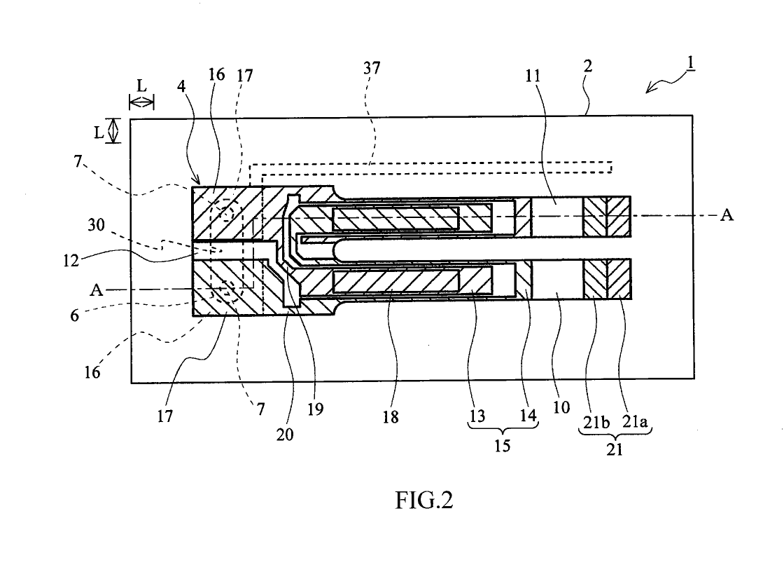

As shown in FIG. 2 and FIG. 3, one through hole (penetration holes) 30 which penetrates the base substrate 2 in the thickness direction and opens in the cavity C is formed in the base substrate 2.

The through hole 30 is formed on a proximal portion side of the piezoelectric vibrating piece 4. The through hole 30 is formed into an oblong shape (or an elliptical shape) such that the through hole 30 includes at least a portion of both mount electrodes 16, 17. The through hole 30 is formed such that a cross-sectional shape of the through hole 30 parallel to the thickness direction of the base substrate 2 becomes a tapered shape.

The shape of the through hole 30 is not limited to such a shape. For example, the through hole 30 may have a circular shape. Also the cross-sectional shape of the through hole 30 parallel to the thickness direction of the base substrate 2 is not always a tapered shape, and may be a rectangular shape. In this case, a volume of the through hole 30 can be decreased, and an amount of low-melting-point glass filled in the through hole 30 can be decreased.

In the through hole 30, sealing glass 6 with which the through hole 30 is filled and two through electrodes 7, 7 which electrically connect the mount electrodes 16, 17 and the external electrodes to each other are arranged.

The sealing glass 6 is formed by baking glass frit in a paste form and firmly adheres to the through hole 30 in a state where the through electrodes 7, 7 arranged in the through hole 30 are fixed by baking, and the sealing glass 6 maintains the air-tightness in the cavity C by completely closing the through hole 30.

The through electrodes 7, 7 are, for example, conductive cores made of 42 alloy and having a columnar shape. The through electrodes 7, 7 are formed such that both ends are flat in the substantially same manner as the sealing glass 6 and a thickness is substantially equal to a thickness of the base substrate 2.

On an outer surface of the base substrate 2, an external electrode 38 which is electrically connected to one through electrode 7 and an external electrode 39 which is electrically connected to the other through electrode 7 are formed. The through electrode 7 and the external electrode 39 are electrically connected to each other by a routing electrode 37b formed by patterning.

As shown in FIG. 1, FIG. 3 and FIG. 4, the lid substrate 3 is a transparent insulation substrate made of a glass material such as soda-lime glass in the substantially same manner as the base substrate 2, for example, and is formed into a plate shape with a size whereby the lid substrate 3 can overlap the base substrate 2 as shown in FIG. 1 to FIG. 4.

A rectangular recessed portion 3a in which the piezoelectric vibrating piece 4 is housed is formed on an inner surface of the lid substrate 3. The recessed portion 3a is a recessed portion for cavity which forms the cavity C for housing the piezoelectric vibrating piece 4 when both substrates 2, 3 are made to overlap each other.

Further, as shown in FIG. 1 to FIG. 4, the lid substrate 3 includes a bonding film 35 at a portion thereof which is brought into contact with the base substrate 2. The lid substrate 3 and the base substrate 2 can be bonded to each other by anodic bonding by means of the bonding film 35. As shown in FIG. 3, the bonding film 35 is formed over the whole surface of the lid substrate 3 on a side where the lid substrate 3 faces the base substrate 2. The bonding film 35 is made of a material which enables anodic bonding (for example, aluminum, silicon, chromium or the like).

The bonding film 35 may be formed only on an outer peripheral surface of the lid substrate 3 or may be formed only on an outer peripheral surface of the base substrate 2 which is brought into contact with the lid substrate 3.

By applying a predetermined drive voltage to the external electrodes 38, 39 formed on the base substrate 2, it is possible to vibrate the pair of vibrating arm portions 10, 11 in the direction that the vibrating arm portions 10, 11 approach each other or are separated from each other with predetermined frequency. Then, the vibrations of the pair of vibrating arm portions 10, 11 can be used as a time source, a timing source of a control signal, a reference signal source or the like.

### (5) Manufacturing Method of Piezoelectric Vibrator

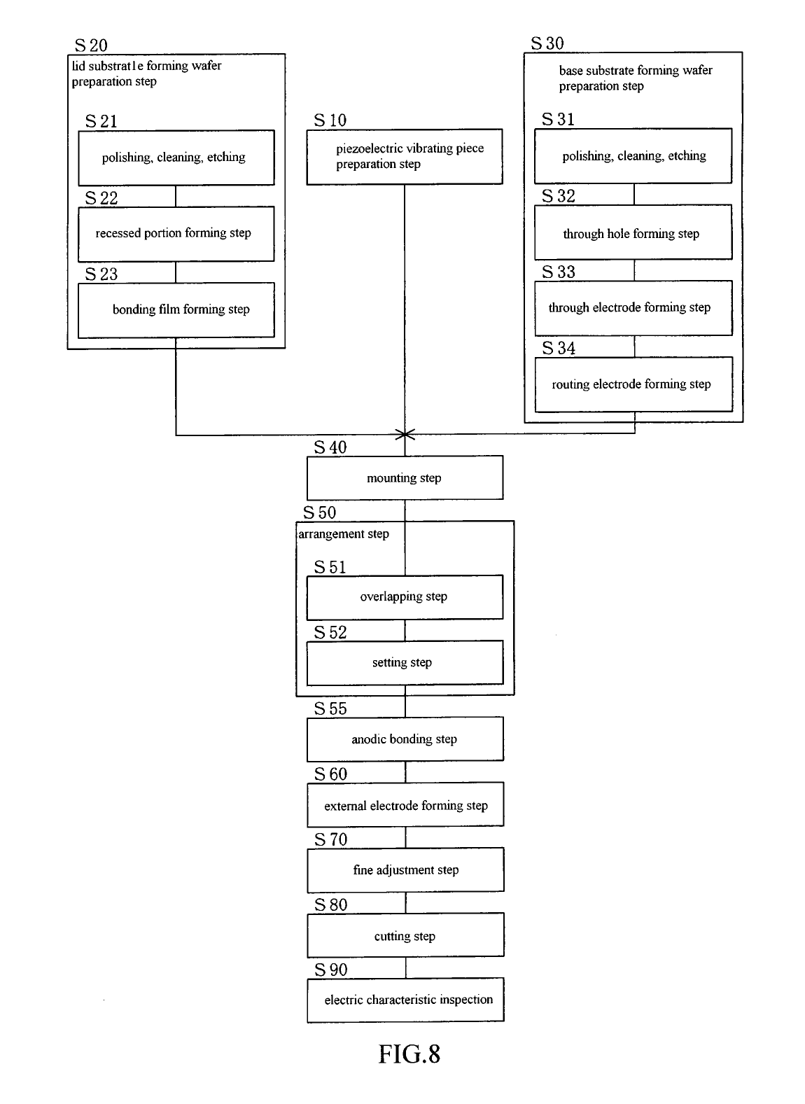

Next, the manufacturing method of the piezoelectric vibrator 1 is explained. FIG. 8 is a flowchart for explaining the manufacturing steps of the piezoelectric vibrator 1.

Although a plurality of piezoelectric vibrators 1 are manufactured at a time by cutting the wafer body formed by bonding the base substrate forming wafer and the lid substrate forming wafer in this embodiment, the manufacturing method of the piezoelectric vibrator 1 is not limited to such a method.

In the method of manufacturing a plurality of piezoelectric vibrators 1, a piezoelectric vibrating piece preparing step (S10), a lid substrate forming wafer preparing step (S20), and a base substrate forming wafer preparing step (S30) are firstly performed. However, these three steps may be performed in any order or may be performed simultaneously.

First of all, the explanation is made with respect to a piezoelectric-vibrating piece preparation step (S10) in which the piezoelectric vibrating piece 4 shown in FIG. 5 to FIG. 7 is prepared.

Firstly, a wafer having a predetermined thickness is formed by slicing a Lambert crystal ore at a predetermined angle. Next, the wafer is subjected to rough working by lapping and, thereafter, a layer of the wafer degenerated by working is removed by etching. Then, the wafer is subjected to mirror finishing such as polishing so that a wafer having a predetermined thickness is formed.

Subsequently, the wafer is cleaned and, thereafter, the wafer is patterned using a photolithography technique in accordance with outer shapes of a plurality of piezoelectric vibrating piece 4 and, at the same time, a metal film is formed and patterned thus forming the excitation electrodes 15, the routing electrodes 19, 20, the mount electrodes 16, 17 and the weight metal film 21. A plurality of piezoelectric vibrating pieces 4 are prepared in accordance with the above-mentioned step.

After preparing the piezoelectric vibrating piece 4, the coarse adjustment of the resonance frequency is performed in such a manner that a laser beam is irradiated to the coarse adjustment film 21a of the weight metal film 21 so as to evaporate the coarse adjustment film 21a partially. The fine adjustment which adjusts the resonance frequency with higher accuracy is performed after mounting the piezoelectric vibrating pieces 4. This adjustment is explained later.

Next, the explanation is made with respect to a lid substrat1e forming wafer preparation step (first wafer preparation step) (S20) in which the lid substrate forming wafer 50 which becomes the lid substrate 3 later is prepared up to a state immediately before anodic bonding. Firstly, soda-lime glass is polished to a predetermined thickness and is cleaned. Thereafter, etching is performed so that the disc-shaped lid substrate forming wafer 50 from which a layer degenerated by working formed on a front surface is removed is formed (S21).

Next, as shown in FIG. 9, a recessed portion forming step is performed (S22). In this step, a plurality of recessed portions 3a for forming the cavities C are formed on an inner surface of the lid substrate forming wafer 50 in a matrix array by etching, press molding at a softening temperature or more or the like (S22).

In this recessed portion forming step, in the same manner as the step for forming the through hole in the base substrate 2, the recessed portions 3a may be formed by pressing a forming mold having projecting portions corresponding to the recessed portions 3a in a state where the lid substrate forming wafer 50 is heated to a softening temperature or more.

Next, a bonding film forming step where the bonding film 35 is formed over the whole inner-surface-side area of the lid substrate forming wafer 50 on which the recessed portions 3a are formed is performed (S23).

Here, the bonding film 35 is formed by vapor deposition, sputtering or the like, for example.

At this point of time, the lid substrate forming wafer preparation step (S20) is finished.

Next, the explanation is made with respect to a base substrate forming wafer preparation step (second wafer preparation step) (S30) in which the base substrate forming wafer 40 which becomes the base substrate 2 later is prepared up to a state immediately prior to anodic bonding.

Firstly, soda-lime glass is polished to a predetermined thickness and is cleaned. Thereafter, etching is performed so that the disc-shaped base substrate forming wafer 40 from which a layer degenerated by working formed on an uppermost front surface is removed is formed (S31).

Next, a through hole forming step is performed (S32). In this step, a plurality of through holes each of which corresponds to one piezoelectric vibrator 1 are formed in the base substrate forming wafer 40. Then, in a through electrode forming step (S33), a pair of through electrodes 7, 7 is arranged in each of the plurality of through holes 30, and powder glass (low-melting-point glass) is filled in the through hole 30 and is baked. Accordingly, it is possible to fix the through electrodes 7, 7 in the through hole 30, and to seal the through hole. Thereafter, by polishing both surfaces of the base substrate 2 such that end surfaces of the through electrodes 7, 7 are exposed to the surfaces, it is possible to ensure electric conductivity of an inner surface side and an outer surface side of the base substrate forming wafer 40.

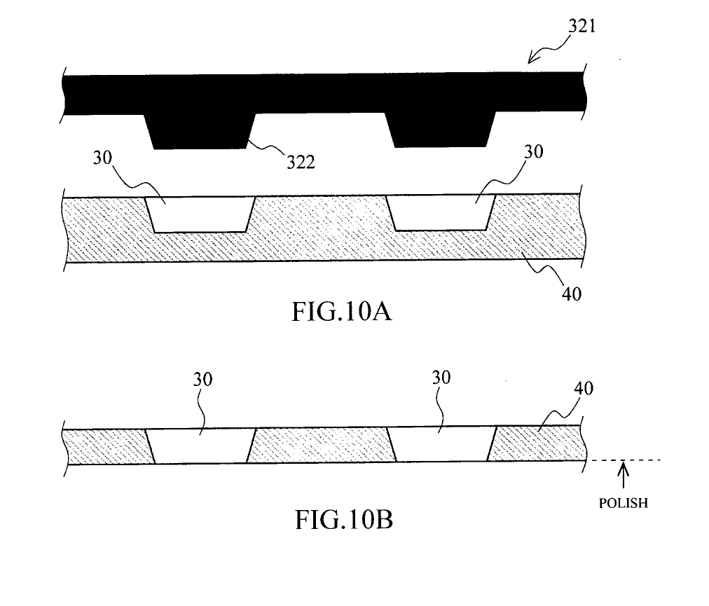

Hereinafter, in conjunction with FIG. 10 to FIG. 12, the through hole forming step (S32) and the through electrode forming step (S33) are explained in detail.

Firstly, in the through hole forming step (S32), a plurality of through holes 30 are formed corresponding to the respective base substrates 2 such that one through hole 30 penetrates in the thickness direction on one longitudinal end side of an area of the base substrate forming wafer 40 corresponding to each cavity C.

To be more specific, as shown in FIG. 10A, a recessed portion corresponding to the through hole 30 is formed on the base substrate forming wafer 40 under an environment at a softening point temperature or more using a forming mold 321.

The through hole 30 is formed into an oblong shape (or elliptical shape) such that the through hole 30 includes at least portions of both mount electrodes 16, 17 formed on the piezoelectric vibrating piece 4. Further, the through hole is formed such that a cross section parallel to the thickness direction of the wafer becomes a tapered shape.

The through hole 30 of this embodiment is formed larger than a conventional through hole and hence, each projecting portion 322 of the forming mold 321 corresponding to the through hole 30 is also formed largely. Accordingly, compared to the conventional forming mold, the forming mold 321 used in this embodiment can enhance the durability thereof.

In the above-mentioned stage, as shown in FIG. 10A, each through hole 30 does not yet penetrate the base substrate forming wafer 40 and hence, as a next step, as shown in FIG. 10B, a surface of the base substrate forming wafer 40 on a side opposite to the forming mold 321 is polished thus allowing the through hole 30 to penetrate the base substrate forming wafer 40.

With respect to the above-explained method, the explanation is made with respect to the case where each through hole 30 is formed by press molding (press working) at a softening point temperature or more. However, a plurality of through holes 30 may be formed by applying other methods such as a sandblast method from one surface of the base substrate forming wafer 40.

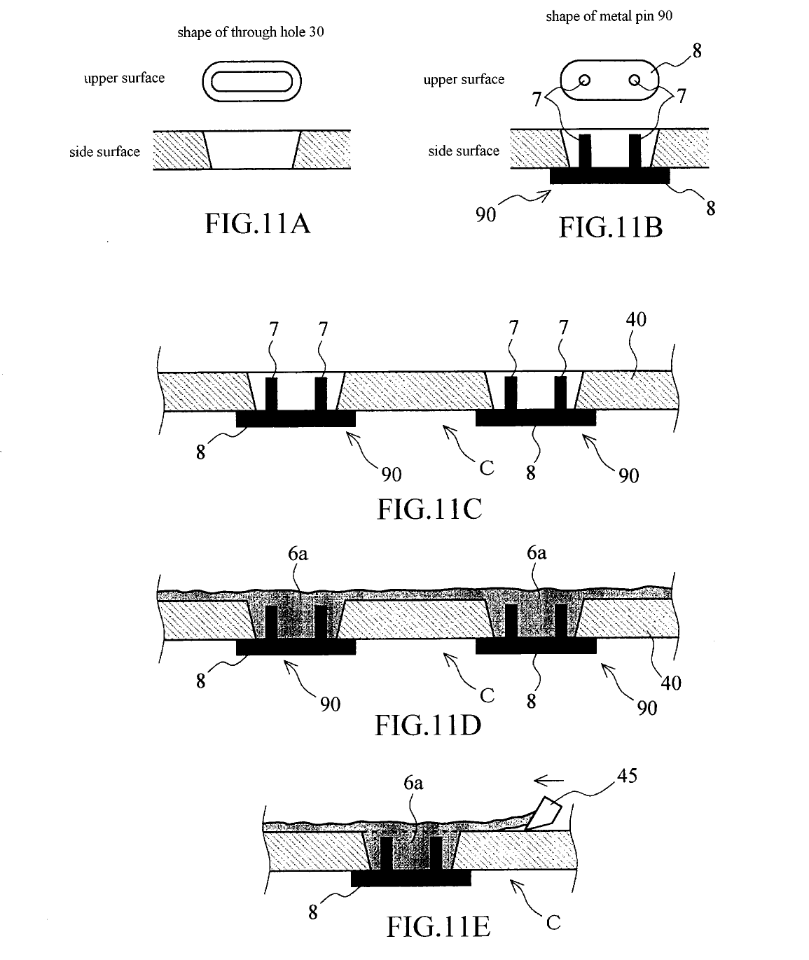

Next, in the through electrode forming step (S33), as shown in FIG. 11A to FIG. 11C, the through electrodes 7, 7 of a metal pin 90 are inserted into the inside of the through hole 30 from a side where an opening area is small until a base plate 8 is brought into contact with the base substrate forming wafer 40.

The metal pin 90 is constituted of the base plate 8 and two through electrodes 7, 7. A shape of the base plate 8 is one size larger than an end-surface opening shape (oblong shape or elliptical shape) of the through hole 30 on a small area side. Accordingly, in a state where the through electrodes 7, 7 are inserted into the through hole 30, the end surface opening of the through hole 30 on a small area side can be closed so that glass frit 6a described later does not leak from a base plate 8 side.

To hold two through electrodes 7, 7 in the through hole 30 in an upright state, the through electrodes 7, 7 having a rod shape with a small diameter are fixed (mounted upright) to the base plate 8 with a predetermined distance therebetween in the direction approximately orthogonal to the base plate 8. Distal ends of the through electrodes 7, 7 are formed flat, and the through electrodes 7, 7 are formed with a length shorter than a thickness of the base substrate forming wafer 40 in a state shown as in FIG. 10B by a predetermined value, for example, 0.02 mm.

Next, as shown in FIG. 11D, glass frit (low-melting-point glass) 6a in a paste form made of a glass material is filled in each through hole 30 from an end-surface opening side having a large area. Here, an opening area of the through hole 30 on a side where the glass frit 6a is filled in the through hole 30 is set larger than an opening area of a conventional one through hole and hence, it is possible to fill the through hole 30 with the glass frit 6a easily and uniformly.

In filling the through hole 30 with the glass frit 6a, a somewhat large amount of glass frit 6a is applied by coating such that the glass frit 6a is surely filled in the through hole 30. Accordingly, the glass frit 6a is also applied to the front surface of the base substrate forming wafer 40 by coating.

Next, to shorten time for a polishing operation described later, the surplus glass frit 6a applied to the base substrate forming wafer 40 by coating is removed.

To be more specific, as shown in FIG. 11E, using a resin-made squeegee 45, for example, a distal end of the squeegee 45 is brought into contact with the front surface of the base substrate forming wafer 40, and is moved along the front surface thus removing the glass frit 6a.

In this embodiment, the length of the through electrodes 7, 7 of the metal pin 90 is set slightly shorter (0.02 mm) than the thickness of the base substrate forming wafer 40 at the time of inserting the metal pin 90 into the through hole 30 and hence, there is no possibility that a distal end 45a of the squeegee 45 and a distal ends of the through electrodes 7, 7 are brought into contact with each other when the squeegee 45 passes above the through hole 30 whereby it is possible to prevent the through electrodes 7, 7 from being inclined with respect to an axis of the through hole 30.

Then, glass frit 6a filled in the through hole 30 is baked at a predetermined temperature. Due to such baking, the through hole 30, the glass frit 6a filled in the through hole 30 and the through electrodes 7, 7 arranged in the glass frit 6a become firmly fixed to each other, and also the base substrate forming wafer 40 and the glass frit 6a become firmly fixed on an inner peripheral surface of the through hole 30.

When the glass frit 6a is baked and solidified, sealing glass 6 is formed.

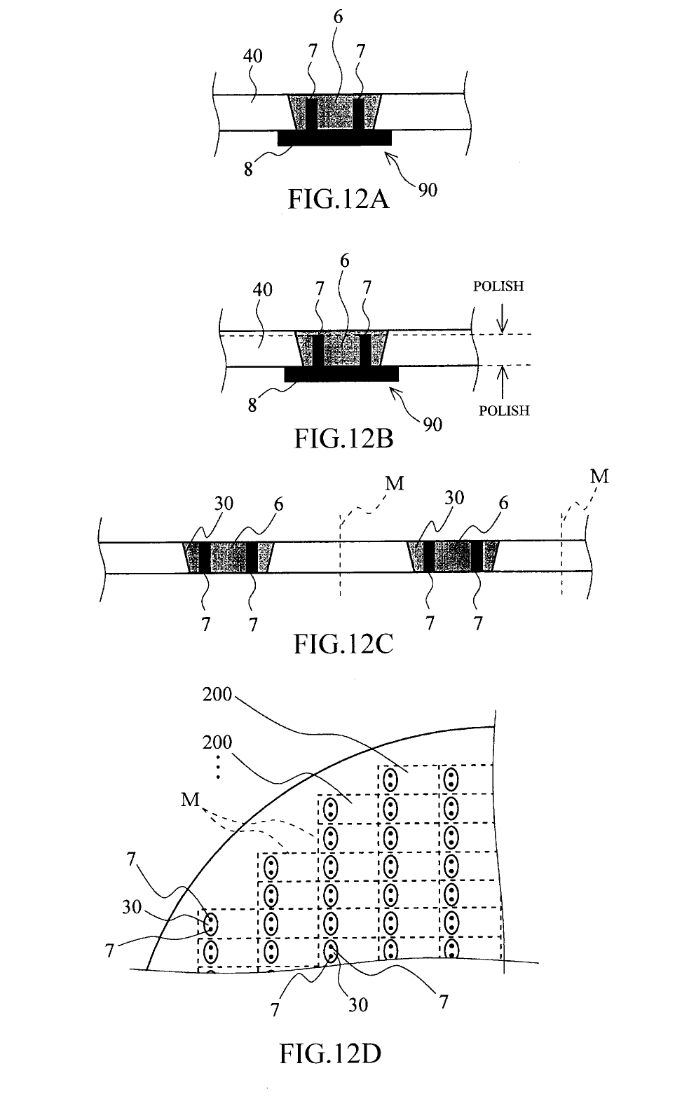

After the glass frit 6a is baked, as shown in FIG. 12A, the distal ends of the through electrodes 7, 7 are formed slightly shorter than the thickness of the base substrate forming wafer 40 so that the through electrodes 7, 7 are embedded in the sealing glass 6, while on a side opposite to the distal ends of the through electrodes 7, 7, both through electrodes 7, 7 are connected to each other by the base plate 8.

Accordingly, as shown in FIG. 12B, the base plate 8 of the metal pin 90 is removed by polishing. As a result, the base plate 8 which has played a role of positioning the sealing glass 6 and the through electrodes 7, 7 is removed, and only the through electrodes 7, 7 are arranged in the sealing glass 6 in a fixed manner.

Simultaneously with the removal of the base plate 8, an upper surface of the base substrate forming wafer 40 is polished until the distal ends of the through electrodes 7, 7 are exposed thus forming the upper surface into a flat surface.

As a result, as shown in FIG. 12C and FIG. 12D, it is possible to form the base substrate forming wafer 40 where the sealing glass 6 and the through electrodes 7, 7 are integrally fixed to each other in the through hole 30.

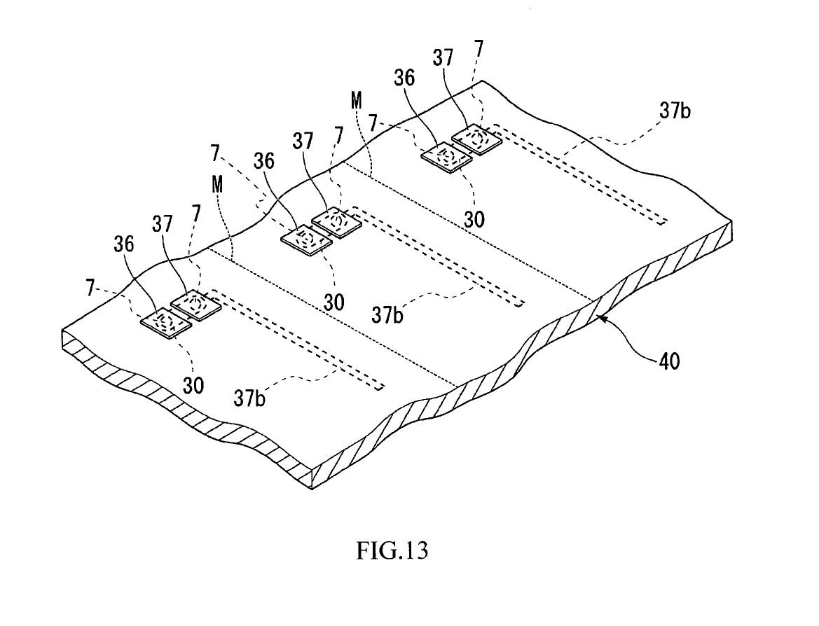

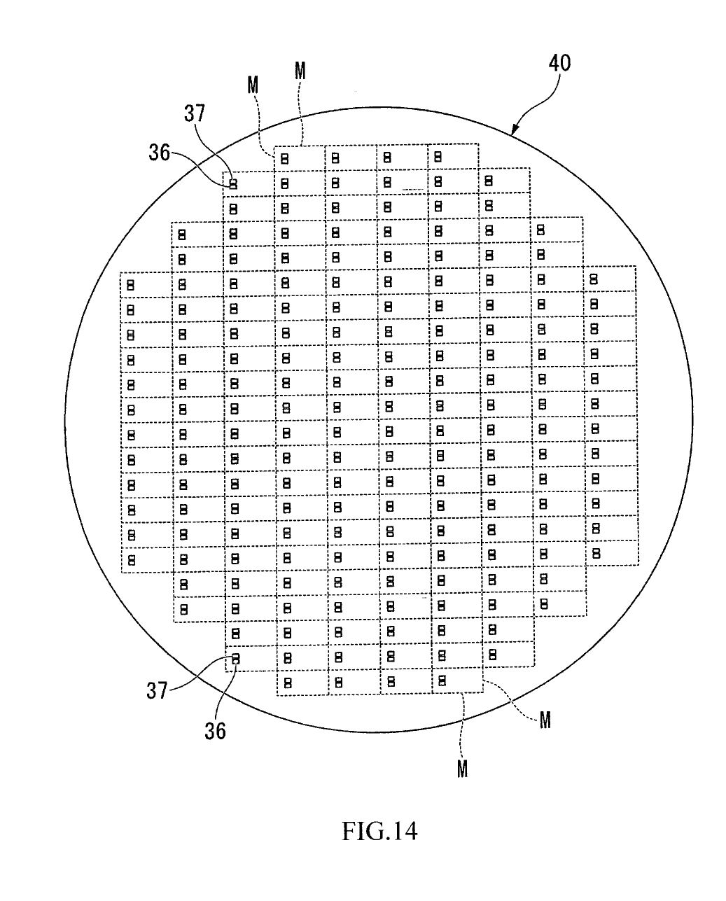

A dotted line M shown in FIG. 12C and FIG. 12D as well as in FIG. 13 and FIG. 14 described later indicates a cutting line which indicates an imaginary line along which the wafers are cut in a cutting step performed later.

Next, as shown in FIG. 13 and FIG. 14, a routing electrode forming step is performed (FIG. 8, S34). In this step, a conducting material is applied to an inner surface of the base substrate forming wafer 40 by patterning thus forming a plurality of routing electrodes 36, 37 which are electrically connected to each pair of through electrodes 7, 7 respectively.

At this point of time, the base substrate forming wafer preparation step (S30) is finished.

In the method of manufacturing a plurality of piezoelectric vibrators 1, a mounting step (piezoelectric vibrating piece mounting step) (S40) is performed after the piezoelectric-vibrating piece preparation step (S10), the lid substrate forming wafer preparation step (S20) and the base substrate forming wafer preparation step (S30).

This mounting step is a step in which the piezoelectric vibrating piece 4 is electrically connected to the routing electrodes 36, 37 such that the piezoelectric vibrating piece 4 is housed in the cavity C in an overlapping step described later.

In this embodiment, the plurality of prepared piezoelectric vibrating pieces 4 are bonded to an inner surface side of the base substrate forming wafer 40 via the routing electrodes 36, 37 and the bumps B respectively. Accordingly, the piezoelectric vibrating piece 4 is brought into a state where the mount electrodes 16, 17 and the routing electrodes 36, 37 are electrically connected to each other. Accordingly, at this point of time, the pair of excitation electrodes 15 of the piezoelectric vibrating piece 4 is brought into a conductive state with the pair of through electrodes 7, 7 respectively.

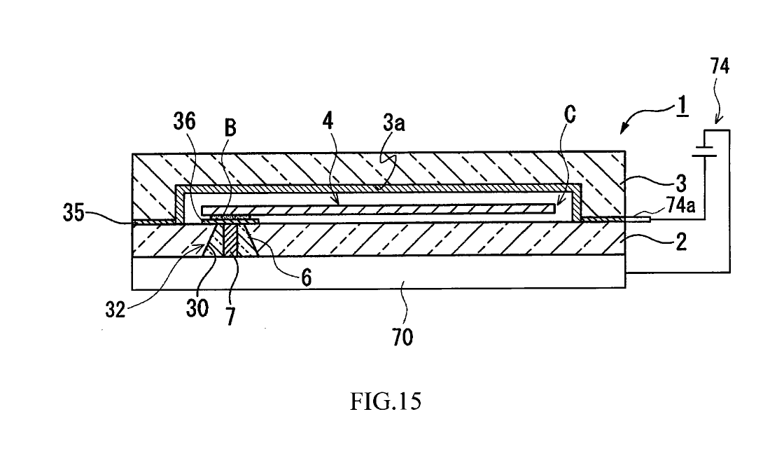

Next, as shown in FIG. 15, an arrangement step is performed (S50). In this step, an inner surface of the lid substrate forming wafer 50 and an inner surface of the base substrate forming wafer 40 are overlapped each other, and an outer surface of the base substrate forming wafer 40 is arranged on an electrode base portion 70 for anodic bonding.

Before explaining the arrangement step, firstly, the electrode base portion 70 for anodic bonding is explained. As shown in FIG. 15, the electrode base portion 70 forms, out of a pair of electrodes which an applying means 74 for anodic bonding arranged in an anodic bonding device not shown in the drawing has, one electrode which functions as a minus terminal. In the example shown in the drawing, the other electrode which functions as a plus terminal out of the pair of electrodes functions as a film-use electrode 74a electrically connected to the bonding film 35. In FIG. 15, a portion of the base substrate forming wafer 40 and a portion of the lid substrate forming wafer 50 corresponding to one piezoelectric vibrator 1 are shown.

The electrode base portion 70 is a conductive plate member which has a size equal to or larger than a size of the base substrate forming wafer 40 as viewed in a plan view, and is made of stainless steel (SUS) or the like, for example.

It may be possible to form recessed portions on a surface of the electrode base portion 70 where the base substrate forming wafer 40 is placed at positions corresponding to the respective through electrodes 7, 7 so as to prevent the through electrodes 7, 7 from coming into contact with the electrode base portion 70.

Further, although the explanation has been made with respect to the case where the electrode base portion 70 according to this embodiment functions as a minus terminal out of the pair of electrodes which the applying means 74 has, it may be also possible to make the electrode base portion 70 function as a plus terminal in place of the minus terminal.

Next, in the arrangement step (S50) is explained in detail.

Firstly, as shown in FIG. 15, an overlapping step in which the lid substrate forming wafer 50 is made to overlap the base substrate forming wafer 40 is performed (S51). Since the base substrate forming wafer 40 and the lid substrate forming wafer 50 corresponding to one piezoelectric vibrator 1 are shown in FIG. 15, the base substrate 2 is shown in place of the base substrate forming wafer 40, and the lid substrate 3 is shown in place of the lid substrate forming wafer 50.

To be more specific, using indexes such as reference marks not shown in the drawing or the like, both wafers 40, 50 are aligned at accurate positions. Accordingly, the mounted piezoelectric vibrating piece 4 is brought into a state where the piezoelectric vibrating piece 4 is housed in the cavity C surrounded by both wafers 40, 50.

Next, a setting step is performed (S52). In this step, both overlapped wafers 40, 50 are put into the anodic bonding device, and the base substrate forming wafer 40 is placed (arranged) on the electrode base portion 70.

Here, a portion of the bonding film 35 which is in contact with the base substrate forming wafer 40 sandwiches the base substrate forming wafer 40 with the electrode base portion 70 over the whole area of the portion.

Further, in this embodiment, the film-use electrode 74a of an applying means 74 is electrically connected to the bonding film 35 at the time of performing the setting step.

With such processing, the arrangement step is finished.

Next, an anodic bonding step is performed (S55). In this step, a bonding voltage (for example, 600V to 800V) is applied between the bonding film 35 and the electrode base portion 70 while heating these parts at a bonding temperature so that the bonding film 35 and the base substrate forming wafer 40 are bonded to each other by anodic bonding.

In the anodic bonding step of this embodiment, the bonding voltage is applied between the electrode base portion 70 and the bonding film 35 while heating these parts at the bonding temperature.

As a result, electrochemical reaction is generated on an interface between the bonding film 35 and the base substrate forming wafer 40 so that both parts are bonded to each other by anodic bonding. Due to such bonding, the piezoelectric vibrating piece 4 is sealed in the cavity C and hence, it is possible to acquire a wafer body 60 shown in FIG. 16 where the base substrate forming wafer 40 and the lid substrate forming wafer 50 are bonded to each other.

In FIG. 16, to facilitate the understanding of the drawing, the wafer body 60 is shown in an exploded state, and a dotted line M shown in FIG. 16 indicates a cutting line along which the wafer body 60 is cut in a cutting step performed later.

After the anodic bonding step is finished, an external electrode forming step (S60) is performed.

In this external electrode forming step, a conductive material is formed on an outer surface of the base substrate forming wafer 40 and is patterned thus forming plural pairs of external electrodes 38, 39 where each pair of external electrodes 38, 39 is electrically connected to the pair of through electrodes 7, 7 respectively.

The external electrodes 38, 39 are arranged on both longitudinal end sides of each piezoelectric vibrator 1. On the other hand, the pair of through electrodes 7, 7 is arranged on a base portion 12 side, that is, an external electrode side of the piezoelectric vibrating piece 4. Accordingly, one through electrode 7 is directly connected to the external electrode 38, and the other through electrode 7 is connected to the external electrode 38 via the external routing electrode 37b.

The routing electrode 37b is also formed by patterning a conductive material in the same manner as the external electrodes 38, 39.

Due to such a step, it is possible to operate the piezoelectric vibrating piece 4 sealed in the cavity C by making use of the external electrode 38, the routing electrode 37b and the external electrode 39.

Next, a fine adjustment step is performed (S70). In this step, frequency of the individual piezoelectric vibrating piece 4 sealed in the cavity C is finely adjusted in a state of the wafer body 60 such that the frequency falls within a predetermined range. To be more specific, a voltage is applied to the pair of external electrodes 38, 39 formed on an outer surface of the base substrate forming wafer 40 thus vibrating the piezoelectric vibrating piece 4. Then, a laser beam is irradiated from the outside through the base substrate forming wafer 40 while measuring frequency thus evaporating the fine adjustment film 21b of the weight metal film 21. Accordingly, a weight of a distal end side of the pair of vibrating arm portions 10, 11 is changed and hence, it is possible to perform the fine adjustment such that the frequency of the piezoelectric vibrating piece 4 falls within a predetermined range of nominal frequency.

It may be possible to adopt the order of steps where the fine adjustment step (S70) is performed after the wafer body 60 is cut into individual piezoelectric vibrators 1 by a cutting step (S80) described later.

However, as described above, by performing the fine adjustment step (S70) prior to the cutting step (S80), the fine adjustment can be performed in a state of the wafer body 60 and hence, it is possible to perform the fine adjustment of the plurality of piezoelectric vibrators 1 more efficiently. Accordingly, this order of steps is preferable in view of the enhancement of the throughput.

After the fine adjustment of frequency is finished, a cutting step is performed (S80). In the cutting step, the bonded wafer body 60 is cut into small pieces along the cutting lines M shown in FIG. 16. As a result, it is possible to manufacture, at a time, a plurality of surface-mounting type piezoelectric vibrators 1 each having the two-layered structure shown in FIG. 1 where the piezoelectric vibrating piece 4 is sealed in the cavity C of the package 9.

Thereafter, an electric characteristic inspection of the inside of the piezoelectric vibrating piece 4 is performed (S90). That is, resonance frequency, a resonance resistance value, drive level characteristic (dependency of resonance frequency and resonance resistance value on excitation power) and the like of the piezoelectric vibrating piece 4 are checked by measuring. Further, the insulation resistance characteristics and the like are also checked. Finally, an appearance inspection of the piezoelectric vibrator 1 is performed, and a size, quality and the like are finally checked. The manufacture of the piezoelectric vibrator 1 is finished with this step.

As has been explained heretofore, according to a manufacturing method of a piezoelectric vibrator of this embodiment, the shape of the through hole is made large so that two metal pins can be inserted into one through hole and, thereafter, frit glass (low-melting-point glass) is filled in the gap and is solidified by baking thus sealing the through hole. Accordingly, the manufacturing method of a piezoelectric vibrator of this embodiment can acquire the following advantages.

(1) A distance between the pair of through electrodes can be narrowed and hence, the piezoelectric vibrator 1 can be miniaturized.

(2) By increasing a volume of the through hole 1, an operation of filling glass frit 6a can be shortened.

(3) although one through hole may become larger than a conventional one through hole, compared to the conventional case where two through holes are formed, a total inner volume of the through hole can be decreased and hence, an amount of glass frit 6a to be filled can be decreased. Further, filling operation time can be also shortened.

(4) The number of through holes can be set to one and hence, bending strength of the piezoelectric vibrator 1 can be increased.

(5) The size of the through hole is increased and the distance between the through holes of two neighboring piezoelectric vibrators can be increased so that the durability of the forming mold 321 for forming the through holes can be enhanced.

(6) Further, a shape of the forming mold 321 can be simplified and hence, a mold working cost can be reduced.

Also in this embodiment, the through electrodes 7, 7 are arranged in one through hole and are fixed by the sealing glass 6 which is integrally formed with the through hole.

Accordingly, compared to a case where two through holes are arranged on both longitudinal sides of the piezoelectric vibrator 1, the piezoelectric vibrator 1 having high bending strength can be acquired.

### (6) Oscillator

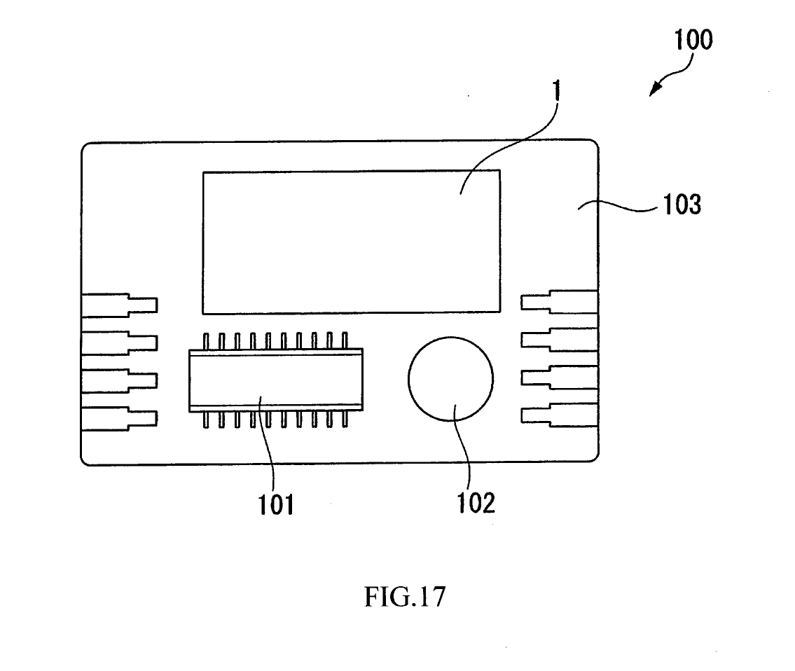

Next, one embodiment of the oscillator according to the present invention is explained in conjunction with FIG. 17.

The oscillator 100 of this embodiment is, as shown in FIG. 17, formed as an oscillating element where the piezoelectric vibrator 1 is electrically connected to an integrated circuit 101. The oscillator 100 includes a substrate 103 on which an electronic part 102 such as a capacitor is mounted. The above-mentioned integrated circuit 101 for oscillator is mounted on the substrate 103, and the piezoelectric vibrator 1 is mounted on the substrate 103 in the vicinity of the integrated circuit 101. The electronic part 102, the integrated circuit 101 and the piezoelectric vibrator 1 are electrically connected with each other by a wiring pattern not shown in the drawing. The respective constitutional parts are molded by a resin not shown in the drawing.

In the oscillator 100 having such a constitution, when a voltage is applied to the piezoelectric vibrator 1, the piezoelectric vibrating piece 4 arranged in the piezoelectric vibrator 1 vibrates. This vibration is converted into an electric signal due to a piezoelectric characteristic which the piezoelectric vibrating piece 4 possesses, and the electric signal is inputted to the integrated circuit 101. Various processing are applied to the inputted electric signal by the integrated circuit 101, and a frequency signal is outputted from the integrated circuit 101. Accordingly, the piezoelectric vibrator 1 functions as an oscillating element.

Further, by selectively setting the constitution of the integrated circuit 101, for example, an RTC (real time clock) module or the like corresponding to a request, it is possible to impart, besides a function as a timepiece-use single-function oscillator or the like, a function of controlling an operation date and time of the oscillator or an external device or a function of providing time, calendar and the like to the oscillator 100.

According to this embodiment, the oscillator 100 includes the high-quality piezoelectric vibrator 1 and hence, the oscillator 100 can also acquire the high quality.

### (7) Electronic Apparatus

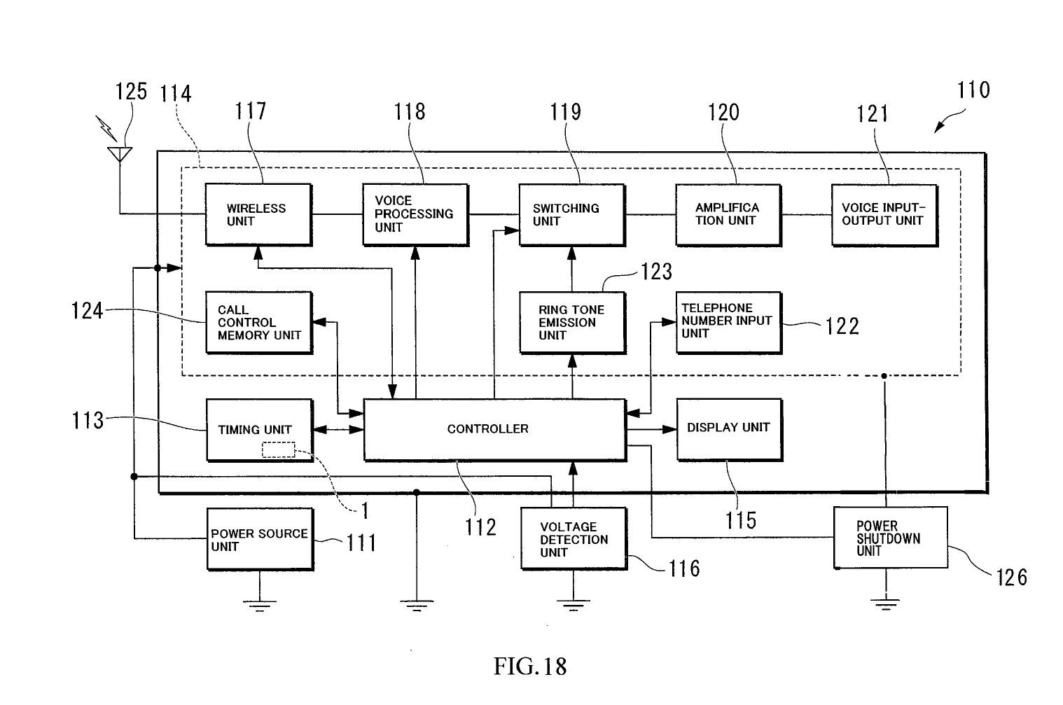

Next, one embodiment of the electronic apparatus according to the present invention is explained in conjunction with FIG. 18. The explanation is made with respect to an example where the electronic apparatus is a portable information device 110 which includes the above-mentioned piezoelectric vibrator 1. Firstly, the portable information device 110 of this embodiment is a device which is represented by a mobile phone, for example, and is a developed or improved form of a wrist watch of the related art.

The portable information device 110 resembles the wrist watch in appearance. A liquid crystal display is arranged on a portion of the portable information device 110 which corresponds to a dial of the wrist watch, and a present time or the like can be displayed on a screen of the liquid crystal display. Further, when the portable information device 110 is used as a communication device, a user removes the portable information device 110 from his wrist, and performs communication in the same manner as a mobile phone of the related art by a speaker and a microphone incorporated into an inner portion of a band. However, the portable information device 110 is remarkably miniaturized and light-weighted compared to the conventional mobile phone.

Next, the constitution of the portable information device 110 of this embodiment is explained. The portable information device 110 includes, as shown in FIG. 18, a piezoelectric vibrator 1 and a power source part 111 for power supply. The power source part 111 is formed of a lithium secondary battery, for example.

To the power source part 111, a control part 112 which performs various controls, a timer part 113 which counts time or the like, a communication part 114 which performs communication with the outside, a display part 115 which displays various information, and a voltage detection part 116 which detects voltages of the respective functional parts are connected to each other in parallel. Electricity is supplied to the respective functional parts from the power source part 111.

The control part 112 performs an operational control of the whole system including the transmission and the reception of voice data, the measurement, display of a present time and the like by controlling the respective functional parts. Further, the control part 112 includes a ROM in which programs are written in advance, a CPU which reads and executes the programs written in the ROM, a RAM which is used as a work area of the CPU and the like.

The timer part 113 includes an integrated circuit which incorporates an oscillation circuit, a register circuit, a counter circuit, an interface circuit and the like therein, and the piezoelectric vibrator 1. When a voltage is applied to the piezoelectric vibrator 1, the piezoelectric vibrating piece 4 vibrates, the vibrations are converted into an electric signal due to a piezoelectric characteristic which crystal possesses, and the electric signal is inputted to the oscillation circuit. An output of the oscillation circuit is binalized and the binalized value is counted by the register circuit and the counter circuit. Then, the transmission/reception of signals is performed between the timer part 113 and the control part 112 via the interface circuit, and a present time, a present date, calendar information and the like are displayed on the display part 115.

The communication part 114 has the substantially same functions as a conventional mobile phone, and includes a wireless part 117, a voice processing part 118, a switching part 119, an amplifying part 120, a voice inputting/outputting part 121, a telephone number inputting part 122, an incoming call sound generation part 123, and a calling-control memory part 124. The wireless part 117 performs the transmission/reception of various data such as voice data with a base station through an antenna 125. The voice processing part 118 performs coding and decoding of a voice signal inputted from the wireless part 117 or the amplifying part 120.

The amplifying part 120 amplifies a signal received from the voice processing part 118 or the voice inputting/outputting part 121 to a predetermined level. The voice inputting/outputting part 121 is formed of a speaker, a microphone or the like, and makes an incoming call sound or a received voice loud or collects voice.

Further, the incoming call sound generation part 123 generates an incoming call sound in response to calling from a base station. The switching part 119 switches the amplifying part 120 connected to the voice processing part 118 to the incoming call sound generation part 123 only when a call arrives so that an incoming call sound generated by the incoming call sound generation part 123 is outputted to the voice inputting/outputting part 121 through the amplifying part 120.

Here, the calling control memory part 124 stores a program relating to an incoming/outgoing call control in communication. Further, the telephone number inputting part 122 includes, for example, numeral keys ranging from 0 to 9 and other keys. By pushing these numeral keys or the like, a user can input the telephone number of the call destination or the like.

The voltage detection part 116, when a voltage applied to the respective functional parts such as the control part 112 from the power source part 111 becomes lower than a predetermined value, detects such lowering of voltage and notifies the lowering of voltage to the control part 112. The predetermined voltage value at this point of time is a value which is preliminarily set as minimum voltage necessary for stably driving the communication part 114, and is set to approximately 3V, for example. The control part 112 which receives the notification of lowering of voltage from the voltage detection part 116 prohibits operations of the wireless part 117, the voice processing part 118, the switching part 119 and the incoming call sound generation part 123. Particularly, the operation stop of the wireless part 117 which consumes large power is inevitable. Further, a message that a remaining battery quantity is short so that the communication part 114 is inoperable is displayed on the display part 115.

That is, due to the operation of the voltage detection part 116 and the operation of the control part 112, an operation of the communication part 114 can be prohibited and a message which indicates the prohibition of the operation of the communication part 114 can be displayed on the display part 115. This display may be formed of a character message. However, as a more intuitive display, a x (bad) mark may be attached to a telephone icon displayed on an upper part of a display screen of the display part 115.

The electronic apparatus is provided with a power source cutting-off part 126 which can selectively cuts off a power source of a portion relating to a function of the communication part 114. In this case, it is possible to stop the function of the communication part 114 more reliably.

According to this embodiment, the portable information device 110 includes the high-quality piezoelectric vibrator 1 and hence, the portable information device 110 can also acquire the high quality.

### (8) Radio-Controlled Timepiece

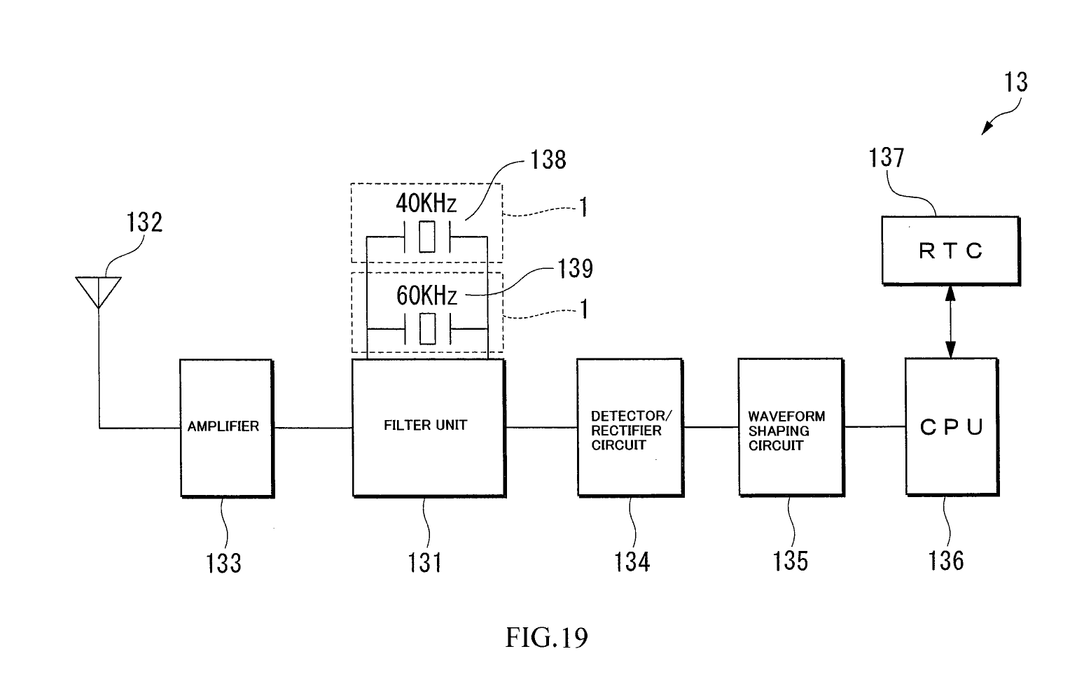

Next, one embodiment of the radio-controlled timepiece according to the present invention is explained in conjunction with FIG. 19.

The radio-controlled timepiece 130 of this embodiment is a timepiece which includes the piezoelectric vibrator 1 which is electrically connected to a filter part 131, and has a function of receiving a standard electric wave containing timepiece information, automatically correcting time to correct time, and displaying the corrected time.

In Japan, transmission installations (transmission stations) which transmit the standard electric wave are located in Fukushima prefecture (40 kHz) and Saga prefecture (60 kHz) and transmit the standard electric waves respectively. A long wave having frequency of 40 kHz or 60 kHz has both of property that the wave propagates on a ground and property that the wave propagates while being reflected between an ionosphere and a ground and hence, the long wave has a wide propagation range whereby the standard electric wave can cover all areas of Japan with the above-mentioned two transmission installations.

The functional constitution of the radio-controlled timepiece 130 is explained in detail hereinafter.

The antenna 132 receives the standard electric wave formed of a long wave having frequency of 40 kHz or 60 kHz. The standard electric wave formed of long wave is an electric wave which is obtained by AM-modulating a carrier wave having frequency of 40 kHz or 60 kHz by time information called as a time code. The received standard electric wave formed of a long wave is amplified by an amplifier 133, and is filtered by a filter part 131 having a plurality of piezoelectric vibrators 1, and is tuned. The piezoelectric vibrators 1 of this embodiment include crystal vibrator parts (piezoelectric vibrating pieces) 138, 139 having resonance frequency of 40 kHz or 60 kHz which is equal to the above-mentioned frequency of the carrier wave respectively.

Further, a filtered signal of predetermined frequency is detected and demodulated by a detection/rectifying circuit 134. Subsequently, the time code is taken out through a waveform shaping circuit 135, and is counted by a CPU 136. The CPU 136 reads information on present year, cumulative days, day of week, time and the like. The read information is reflected on an RTC 137 so that correct time information is displayed.

The carrier wave has frequency of 40 kHz or 60 kHz and hence, the crystal vibrator parts 138, 139 are preferably formed of a vibrator having the above-mentioned tuning-fork structure.

Although the above-mentioned explanation is made with respect to the radio-controlled timepiece used in Japan, the frequencies of standard electric waves of long wave used overseas differ from the standard electric wave used in Japan. For example, the standard electric wave having frequency of 77.5 kHz is used in Germany. Accordingly, in incorporating the radio-controlled timepiece 130 also compatible with the oversea use into a portable device, the piezoelectric vibrator 1 having frequency different from the frequency used in Japan becomes necessary.

According to this embodiment, the radio-controlled timepiece 130 includes the high-quality piezoelectric vibrator 1 and hence, the radio-controlled timepiece 130 can also acquire the high quality.

The technical scope of the present invention is not limited to the above-mentioned embodiments, and the various modifications are conceivable without departing from the gist of the present invention.

For example, although the explanation has been made by taking the piezoelectric vibrating piece 4 having grooves where the groove portions 18 are formed on both surfaces of the vibrating arm portions 10, 11 as an example of the piezoelectric vibrating piece 4 in the above-mentioned embodiment, a piezoelectric vibrating piece of a type which has no groove portions 18 may be also used. However, electric field efficiency between the pair of excitation electrodes 15 at the time of applying a predetermined voltage to the pair of excitation electrodes 15 can be increased by forming the groove portions 18 and hence, a vibration loss can be further suppressed and thereby the vibration characteristic is further improved. That is, a CI value (Crystal Impedance) can be further lowered and hence, the piezoelectric vibrating piece 4 can acquire the higher performance. It is desirable to form the groove portions 18 from this viewpoint.

Further, in the above-mentioned embodiment, the explanation has been made by taking the tuning-fork-type crystal vibrator as the piezoelectric vibrator as an example. However, it is possible to use other piezoelectric vibrators, for example, various vibrators such as an AT vibrator or a combined vibrator where plural vibration modes are combined.

Further, in the above-mentioned embodiment, the explanation has been made with respect to the case where the manufacturing method of a package according to the present invention is applied to the manufacturing method of the piezoelectric vibrator where the piezoelectric vibrator 1 in which the piezoelectric vibrating piece 4 is housed in the routing electrodes 36, 37 in the cavity C of the package 9. However, the manufacturing method of the package according to the present invention is also applicable to a case where a package in which wiring different from wiring to the piezoelectric vibrating piece 4 is electrically connected to the routing electrodes 36, 37 is manufactured.

Further, the constitutional elements of the above-mentioned embodiment may be suitably replaced with well-known constitutional elements or the above-mentioned modifications may be suitably combined to each other without departing from the gist of the present invention.

What is claimed is:

1. A method for producing piezoelectric vibrators, comprising:
(a) defining a plurality of first substrates on a first wafer and a plurality of second substrates on a second wafer;
(b) forming a single through-hole in a respective at least some of the first substrates on the first wafer;
(c) securing a pair of conductive columns in a respective at least some of the through-holes;
(d) securing a piezoelectric vibrating piece on a respective at least some of the first substrates in which the pair of conductive columns are secured in the through-hole, wherein securing a piezoelectric vibrating piece comprises electrically connecting mount electrodes of the a piezoelectric vibrating piece, respectively, to the pair of conductive columns;
(e) layering the first and second wafers such that at least some of the first substrates on which the piezoelectric vibrating piece is secured substantially coincide respectively with at least some of the corresponding second substrates;
(f) anodically bonding a respective at least some of the coinciding first and second substrate pairs which each include the conductive layer patterned therein; and
(g) cutting off from the first and second wafers a respective at least some of the bonded first and second substrate pairs.

2. The method according to claim 1, wherein forming a single through-hole comprises forming a single thorough-hole with a tapered inner wall.

3. The method according to claim 1, where forming a single through-hole comprises forming a single through-hole with a cross-section being in a form of an elongated circle.

4. The method according to claim 1, wherein forming a single through-hole in a respective at least some of the first substrates on the first wafer comprises forming recesses with a bottom in one surface of the first wafer and removing the other surface of the first wafer to make the recesses go through to the other surface.

5. The method according to claim 1, wherein securing a pair of conductive columns comprises placing the pair of conductive columns in the through-hole with a distance between the conductive columns.

6. The method according to claim 5, wherein securing a pair of conductive columns further comprises filling, with glass paste, the through-hole in which the pair of conductive columns are placed.

7. The method according to claim 6, wherein securing a pair of conductive columns further comprises hardening the glass paste inside the through-hole under heat.

8. The method according to claim 7, wherein securing a pair of conductive columns further comprises removing at least one surface of the first wafer to expose the pair of conductive columns.

9. The method according to claim 1, further comprising forming a conductive pattern on a surface of a respective at least some of the first substrates in which the pair of conductive columns are secured in the through-hole, wherein the conductive patter runs from one of the conductive columns for connection with an external electrode.

10. The method according to claim 1, wherein electrically connecting mount electrodes of the piezoelectric vibrating piece, respectively, to the pair of conductive columns comprises placing the mount electrodes over the conductive columns.

11. A piezoelectric vibrator comprising:
a hermetically closed casing comprising first and second substrates with a cavity inside, which are anodically bonded together, wherein the first substrate is formed with a single through-hole in which a pair of conductive columns are secured in a plug which hermetically closes the through-hole; and
a piezoelectric vibrating piece secured inside the cavity whose mount electrodes are electrically connected, respectively, to the pair of conductive columns.

12. The piezoelectric vibrator according to claim 11, wherein the mount electrodes are placed over the conductive columns.

13. The piezoelectric vibrator according to claim 12, further comprising electrode plates present between the mount electrodes and the conductive columns.

14. The piezoelectric vibrator according to claim 12, wherein further comprising conductive bumps present between the mount electrodes and the conductive columns.

15. The piezoelectric vibrator according to claim 11, wherein the through-hole has a cross-section in a form of an elongated circle.

16. An oscillator comprising the piezoelectric vibrator defined in claim 11.

17. An electronic device comprising a clock section to which the piezoelectric vibrator defined in claim 11 is electrically connected.

18. A radio-controlled timepiece comprising a filer to which the piezoelectric vibrator is electrically connected.
